(19) United States
(12) Patent Application Publication
(10) Pub. No.: US 2019/0279884 A1
(43) Pub. Date: Sep. 12, 2019

(54) SUBSTRATE DRYING APPARATUS

(71) Applicant: Tokyo Electron Limited, Tokyo (JP)

(72) Inventors: Koji Yamashita, Koshi City (JP); Yoshihiro Kai, Koshi City (JP)

(21) Appl. No.: 16/299,371

(22) Filed: Mar. 12, 2019

(30) Foreign Application Priority Data
Mar. 12, 2018 (JP) 2018-044174

(51) Int. Cl. H01L 21/67; H01L 21/687; H01L 21/677

(52) U.S. Cl. CPC H01L 21/67034; H01L 21/67751; H01L 21/68742

(57) ABSTRACT

A drying fluid can be uniformly supplied to a substrate. A substrate drying apparatus includes a processing chamber and a cover unit. The processing chamber is provided with an opening through which the substrate is carried in and out. The cover unit is configured to open or close the opening. Further, the cover unit includes a diffusion space and a rectifying member. The diffusion space is configured to diffuse a drying fluid therein. The rectifying member is configured to rectify a flow of the drying fluid diffused in the diffusion space and allow the rectified drying fluid to be flown out into the processing chamber from the diffusion space.

### CROSS-REFERENCE TO RELATED APPLICATION

This application claims the benefit of Japanese Patent Application No. 2018-044174 filed on Mar. 12, 2018, the entire disclosures of which are incorporated herein by reference.

### TECHNICAL FIELD

The various aspects and embodiments described herein pertain generally to a substrate drying apparatus.

### BACKGROUND

Conventionally, there is known a substrate drying apparatus configured to dry a substrate after a liquid processing is performed on the substrate. By way of example, Patent Document 1 discloses a substrate drying apparatus which is equipped with: a processing chamber placed at an upper portion of a liquid processing tub; a transfer unit configured to transfer the substrate subjected to the liquid processing in the liquid processing tub into the processing chamber; and a supply nozzle provided within the processing chamber and configured to supply a drying fluid into the processing chamber.

Patent Document 1: Japanese Patent Laid-open Publication No. 2016-119436

In the aforementioned prior art, however, there is still a room for improvement in that the drying fluid needs to be uniformly supplied to the substrate placed in the processing chamber.

### SUMMARY

In view of the foregoing, an exemplary embodiment provides a substrate drying apparatus capable of uniformly supplying a drying fluid to a substrate.

In an exemplary embodiment, a substrate drying apparatus configured to dry a substrate is provided. The substrate drying apparatus includes a processing chamber and a cover unit. The processing chamber is provided with an opening through which the substrate is carried in and out. The cover unit is configured to open or close the opening. Further, the cover unit includes a diffusion space and a rectifying member. The diffusion space is configured to diffuse a drying fluid therein. Further, the rectifying member is configured to rectify a flow of the drying fluid diffused in the diffusion space and allow the rectified drying fluid to be flown out into the processing chamber from the diffusion space.

According to the exemplary embodiment, it is possible to uniformly supply the drying fluid to the substrate.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional view of a substrate processing apparatus according to an exemplary embodiment;

FIG. 2 is a schematic plan view of a cover unit according to the exemplary embodiment;

FIG. 3 is a schematic plan view of a nozzle according to the exemplary embodiment;

FIG. 4 is a schematic plan view of a rectifying member according to the exemplary embodiment;

FIG. 5 is a schematic diagram illustrating a downflow formed within a processing chamber according to the exemplary embodiment;

FIG. 6 is a schematic cross sectional view illustrating a configuration of a supply path for a drying fluid;

FIG. 7 is a schematic cross sectional view illustrating a state in which an upstream supply path and a downstream supply path are connected;

FIG. 8 is a flowchart illustrating an example sequence of a processing performed by the substrate processing apparatus according to the exemplary embodiment;

FIG. 9 is a diagram illustrating an operation example of a first carry-in processing;

FIG. 10 is a diagram illustrating an operation example of a liquid processing;

FIG. 11 is a diagram illustrating an operation example of a second carry-in processing;

FIG. 12 is a diagram illustrating an operation example of a drying processing;

FIG. 13 is a diagram illustrating an operation example of a carry-out processing;

FIG. 14 is a schematic cross sectional view of a substrate processing apparatus according to a modification example; and

FIG. 15 is a schematic cross sectional view of the substrate processing apparatus according to the modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments for a substrate drying apparatus according to the present disclosure will be described in detail with reference to the accompanying drawings. However, it should be noted that the substrate drying apparatus of the present disclosure is not limited by the exemplary embodiments. Further, the various exemplary embodiments can be appropriately combined as long as the contents of processings are not contradictory. Further, in the description of the following exemplary embodiments, same parts will be assigned same reference numerals, and redundant description will be omitted.

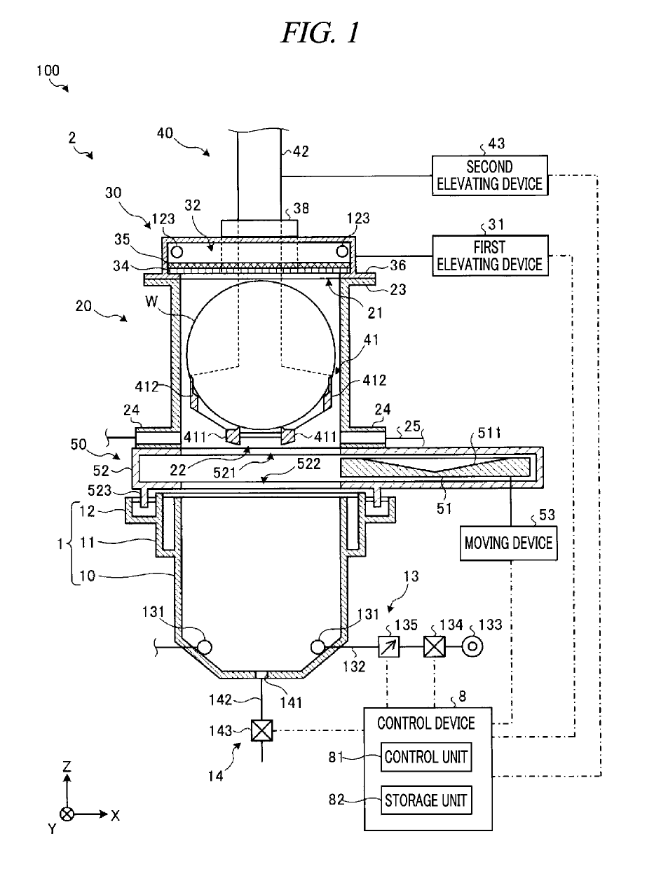

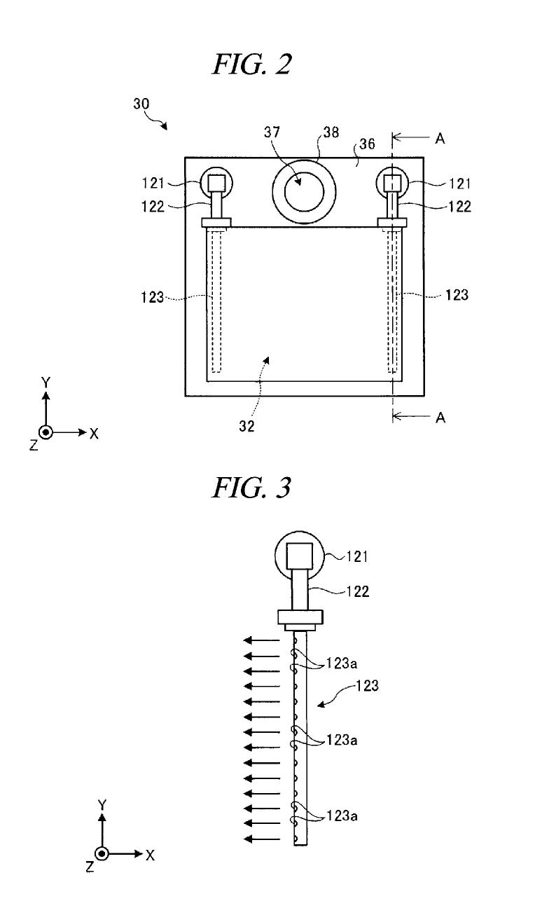

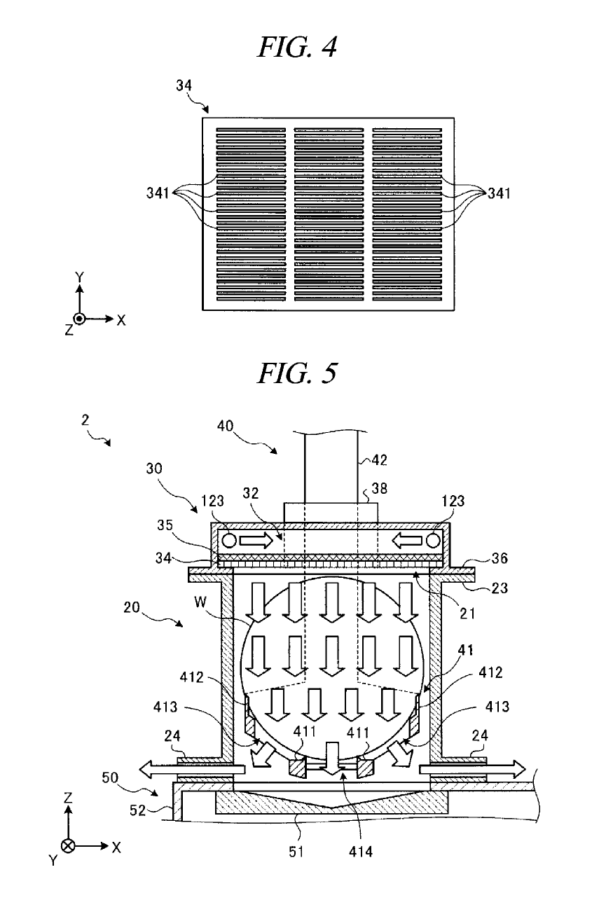

First, a configuration of a substrate processing apparatus according to an exemplary embodiment will be described with reference to FIG. 1 to FIG. 4. FIG. 1 is a schematic cross sectional view of a substrate processing apparatus according to the exemplary embodiment; FIG. 2 is a schematic plan view of a cover unit according to the exemplary embodiment; FIG. 3, a schematic plan view of a nozzle according to the exemplary embodiment; and FIG. 4, a schematic plan view of a rectifying member according to the exemplary embodiment.

As depicted in FIG. 1, a substrate processing apparatus 100 is equipped with: a liquid processing tub 1 configured to perform a liquid processing on a semiconductor substrate such as a silicon wafer (hereinafter, simply referred to as “wafer W”); and a substrate drying apparatus 2 provided above the liquid processing tub 1 and configured to dry the wafer W after being subjected to the liquid processing. Further, the substrate processing apparatus 100 includes a control device 8 configured to control the liquid processing tub 1 and the substrate drying apparatus 2.

The liquid processing tub 1 includes a storage tub 10, an overflow tub 11 and a seal tub 12. Each of the storage tub 10, the overflow tub 11 and the seal tub 12 has an opening at an upper portion thereof and stores a processing liquid therein.

The storage tub 10 is formed to have a size in which multiple wafers W are immersed therein at the same time. The overflow tub 11 is formed at an outer peripheral portion of an upper end of the storage tub 10 and stores therein the processing liquid overflown from the storage tub 10. The seal tub 12 is formed at an outer peripheral portion of an upper end of the overflow tub 11 and stores therein pure water or the like. By immersing a seal piece 523 of a shielding mechanism 50 to be described later in the pure water or the like stored in the seal tub 12, the inside and the outside of the liquid processing tub 1 can be isolated from each other.

The liquid processing tub 1 is equipped with a processing liquid supply device 13 configured to supply the processing liquid; and a processing liquid drain device 14 configured to drain the processing liquid.

The processing liquid supply device 13 is equipped with: a plurality of (here, two) processing liquid discharge nozzles 131; a supply path 132; a processing liquid supply source 133; a valve 134; and a flow rate controller 135. The two processing liquid discharge nozzles 131 are provided at a bottom portion within the storage tub 10. The supply path 132 connects the processing liquid discharge nozzles 131 and the processing liquid supply source 133. The processing liquid source 133 supplies the processing liquid to the two processing liquid discharge nozzles 131. Here, it is assumed that a rinse liquid such as pure water is supplied as the processing liquid. The valve 134 is provided at a portion of the supply path 132 and configured to open or close the supply path 132. The flow rate controller 135 is provided at a portion of the supply path 132 and configured to adjust a flow rate of the processing liquid flowing in the supply path 132. The valve 134 and the flow rate controller 135 are connected to and controlled by a control unit 81 of the control device 8.

The processing liquid supply device 13 supplies the processing liquid supplied from the processing liquid supply source 133 into the storage tub 10 through the processing liquid discharge nozzles 131. Accordingly, the processing liquid is stored in the storage tub 10.

The processing liquid drain device 14 is equipped with a drain hole 141, a drain path 142 and a valve 143. The drain hole 141 is formed at a center of the bottom portion within the storage tub 10. The drain path 142 is connected to the drain hole 141. The valve 143 is provided at a portion of the drain path 142 and configured to open or close the drain path 142. The valve 143 is connected to the control unit 81, and an opening/closing operation of the valve 143 is controlled by the control unit 81.

By opening the valve 143, the processing liquid drain device 14 drains the processing liquid stored in the storage tub 10 into the drain path 142 from the drain hole 141.

The substrate drying apparatus 2 is equipped with a processing chamber 20, a cover unit 30, a transfer unit 40 and the shield mechanism 50.

The processing chamber 20 is formed to have a size in which multiple wafers W are accommodated at the same time. A first opening 21 is provided at an upper portion of the processing chamber 20, and a second opening 22 is provided at a lower portion thereof. The first opening 21 is an opening through which the wafers W are carried in and out between the outside of the substrate processing apparatus 100 and the processing chamber 20. The second opening 22 is an opening through which the wafers W are carried in and out between the processing chamber 20 and the storage tub 10.

The processing chamber 20 is equipped with a first flange 23. The first flange 23 is provided around the first opening 21. To elaborate, the first flange 23 is protruded horizontally outwards from an edge of the first opening 21.

The processing chamber 20 has a plurality of (here, two) exhaust ports 24. The two exhaust ports 24 are located under the wafers W which are placed within the processing chamber 20. The two exhaust ports 24 are arranged symmetrically in a direction (X-axis direction) perpendicular to an arrangement direction (Y-axis direction) of the wafers W. The two exhaust ports 24 is connected to an exhaust path 25, and an atmosphere within the processing chamber 20 is exhausted to the outside of the substrate drying apparatus 2 through the exhaust ports 24 and the exhaust path 25.

The cover unit 30 is provided above the processing chamber 20 and closes the first opening 21 of the processing chamber 20. To elaborate, the cover body 30 has a second flange 36 which is provided at a position facing the first flange 23 of the processing chamber 20. As the second flange 36 comes into contact with a seal member (a seal member 119 to be described later) provided at the first flange 23, the cover unit 30 closes the first opening 21 of the processing chamber 20.

The cover unit 30 is connected to a first elevating device 31. The first elevating device 31 moves the cover unit 30 up and down between a closing position where the cover unit 30 closes the first opening 21 and an opening position which is located above the closing position and where the cover unit 30 opens the first opening 21. The first elevating device 31 is connected to and controlled by the control unit 81.

The cover unit 30 has a diffusion space 32, a plurality of (here, two) nozzles 123, a rectifying member 34 and a pressure loss member 35.

The diffusion space 32 is provided above the first opening 21 in the state that the cover unit 30 is located at the closing position shown in FIG. 1, and communicates with the processing chamber 20 via the rectifying member 34 and the pressure loss member 35.

The two nozzles 123 are provided within the diffusion space 32 and configured to supply a drying fluid into the diffusion space 32. To be specific, as depicted in FIG. 2, each nozzle 123 has an elongated shape extended in the arrangement direction (Y-axis direction) of the wafers W held by the transfer unit 40 to be described later. Further, as shown in FIG. 3, each nozzle 123 discharges the drying fluid horizontally from a multiple number of discharge openings 123a formed along a lengthwise direction thereof.

Each nozzle 123 is connected to a connecting member 121 via a joint member 122, and the drying fluid is introduced into the nozzles 123 within the diffusion space 32 from the connecting member 121 via the joint member 122. A supply path for the drying fluid will be elaborated later.

The rectifying member 34 is a plate-shaped member corresponding to a ceiling of the processing chamber 20, and is configured to rectify a flow of the drying fluid diffused in the diffusion space 32 and allows this drying fluid to be flown out into the processing chamber 20 from the diffusion space 32. To elaborate, as shown in FIG. 4, the rectifying member 34 is provided with a multiple number of slits 341. As the drying fluid passes through these slits 341, the flow of the drying fluid is rectified in a certain direction.

The pressure loss member 35 is a plate-shaped member placed on the rectifying member 34. This pressure loss member 35 causes a pressure loss of the drying fluid which is introduced into the rectifying member 34 from the diffusion space 32. Besides a porous member made of a resin, ceramic or a nonwoven fabric, a plate-shaped member provided with multiple openings formed by punching (a punching board) may be used as the pressure loss member 35.

Further, as illustrated in FIG. 1 and FIG. 2, the cover unit 30 has an insertion through hole 37 through which an arm 42 of the transfer unit 40 is inserted; and a sealing member 38 configured to seal a gap between the insertion through hole 37 and the arm 42. The insertion through hole 37 and the sealing member 38 are provided at the second flange 36.

The sealing member 38 is equipped with a supply unit (not shown) configured to supply a purge gas into a gap between the insertion through hole 37 and the arm 42 and an exhaust unit (not shown) configured to exhaust the purge gas from the gap between the insertion through hole 37 and the arm 42. The sealing member 38 sets a pressure within the gap between the insertion through hole 37 and the arm 42 to be higher than a pressure within the processing chamber 20 by supplying the purge gas into the gap between the insertion through hole 37 and the arm 42, so that a leakage of the drying fluid from the inside of the processing chamber 20 to the outside thereof can be suppressed. A flow rate of the purge gas is adjusted by a non-illustrated flow rate controllers such that the purge gas supplied into the gap between the insertion through hole 37 and the arm 42 does not flow into the processing chamber 20.

Furthermore, the sealing member 38 may not be limited to a member configured to seal the gap between the insertion through hole 37 and the arm 42 by the gas but may be of a type configured to physically seal the gap between the insertion through hole 37 and the arm 32 by using, for example, an inflate seal or the like. The inflate seal is a tube-shaped seal member made of a resin. By supplying a gas into the inflate seal, the inflated seal is expanded to seal the gap between the insertion through hole 37 and the arm 42.

The transfer unit 40 is equipped with: a holding unit 41 configured to hold the wafers W at the same time; the arm 42 configured to support the holding unit 41; and a second elevating device 43 configured to move the arm 42 up and down.

The holding unit 41 holds the wafers W in a standing-up posture while maintaining a regular gap therebetween in the horizontal direction. To elaborate, the holding unit 41 is equipped with: two first guide members 411 configured to support lower periphery portions of the wafers W; and two second guide members 412 configured to support peripheral portions of the wafers W from positions higher than those of the first guide members 411. That is, each wafer W is supported at four points by the first guide members 411 and the second guide members 412

The arm 42 is a vertically elongated member and supports the holding unit 41 with a lower portion thereof. The arm 42 is connected to the second elevating device 43. The second elevating device 43 moves the arm 42 up and down in the vertical direction. The second elevating device 43 is connected to and controlled by the control unit 81.

The shielding mechanism 50 includes a shielding door 51, a casing 52 and a moving device 53. The shielding door 51 is formed to have a size in which the second opening 22 of the processing chamber 20 is closed. An inclined surface 511, which is inclined downwards toward a center from a periphery thereof, is formed at a top surface of the shielding door 51, and a non-illustrated drain opening is formed at a central portion of the inclined surface 511. In a drying processing to be described later, the processing liquid removed from the wafers W or the like is collected into the non-illustrate drain opening to be drained to the outside of the substrate drying apparatus 2 from the drain opening.

The casing 52 is provided between the liquid processing tub 1 and the processing chamber 20 and accommodates the shielding door 51 therein. The casing 52 has a third opening 521 at a position facing the second opening 22 of the processing chamber 20 and a fourth opening at a position facing the opening of the storage tub 10. The processing chamber 20 and the storage tub 10 communicate with each other via the casing 52.

The seal piece 523 projecting downwards is provided at a bottom surface of the casing 52. The seal piece 523 is immersed in the pure water stored in the seal tub 12. Accordingly, the inside of the liquid processing tub 1 can be isolated from the outside.

The moving device 53 is connected to the shielding door 51 and moves the shielding door 51 both horizontally and vertically. Accordingly, the moving device 53 is capable of moving the shielding door 51 between a closing position where the shielding door 51 closes the second opening 22 and an opening position where the shielding door 51 opens the second opening 22. The moving device 53 is connected to the control unit 81, and an opening/closing operation thereof is controlled by the control unit 81. Further, the opening position is located at a side of the closing position to avoid interference between the wafer W and the shielding door 51.

The control device 8 is, by way of example, a computer and includes the control unit 81 and a storage unit 82. The storage unit 82 is implemented by a semiconductor memory device such as, but not limited to a RAM or a flash memory or a storage device such as, but not limited to, a hard disk or an optical disk. Further, the storage unit 82 stores therein a program controlling various processings performed in the substrate processing apparatus 100. This control unit 81 includes a micro-computer having a CPU (Central Processing Unit), a ROM (Read Only Memory), a RAM (Random Access Memory), an input/output port, and so forth; and various kinds of circuits, and controls an operation of the substrate drying apparatus 100 by reading out and executing the program stored in the storage unit 82.

Further, this program may be recorded in a computer-readable recording medium and installed to the storage unit 82 of the control device 8 from the recording medium. The computer-readable recording medium may be, by way of example, but not limitation, a hard disk (HD), a flexible disk (FD), a compact disk (CD), a magnet optical disk (MO), a memory card, of the like.

As shown in FIG. 5, the cover unit 30 according to the exemplary embodiment discharges the drying fluid, which is supplied from the nozzles 123 into the diffusion space 42, after rectifying the flow of the drying fluid by the rectifying member 34. Accordingly, a downflow of the drying fluid vertically flowing downwards from the rectifying member 34 corresponding to the ceiling of the processing chamber 20 can be formed within the processing chamber 20. Further, by supplying the drying fluid to the rectifying member 34 after diffusing it within the diffusion space 32, not by supplying the drying fluid to the rectifying member 34 directly, it is possible to suppress non-uniformity in the flow rate of the drying fluid discharged from the rectifying member 34. As a result, the downflow can be formed uniformly. By forming the downflow of the drying fluid within the processing chamber 20, the drying fluid is supplied uniformly to the wafers W placed in the processing chamber 20. Thus, non-uniformity in drying degree may not be caused between the wafers W or within a surface of a single sheet of wafer W.

Furthermore, in the cover unit 30 according to the exemplary embodiment, the pressure loss is generated on the drying fluid introduced into the slits 341 of the rectifying member 34 by providing the pressure loss member 35 above the rectifying member 34. Accordingly, since the drying fluid is diffused within the diffusion space 32 with a higher density, generation of the non-uniformity in the flow rate of the drying fluid discharged from the rectifying member 34 can be further suppressed, so that an appropriate downflow without suffering swirling-up or the like can be formed within the processing chamber 20.

Since the exhaust ports 24 for the drying fluid are provided under the wafers W which are placed within the processing chamber 20, it is easy to maintain the downflow up to under the wafers W. Further, a gap 413 is provided between the first guide member 411 and the second guide member 412 of the holding unit 41, and a gap 414 is provided between the two first guide members 411. The drying fluid is introduced into the exhaust ports 24 through these gaps 413 and 414. In this way, by providing the gaps 413 and 414 at the holding unit 41, a turbulent flow of the drying fluid, which reaches the exhaust ports 24 from below the wafers W, can be suppressed.

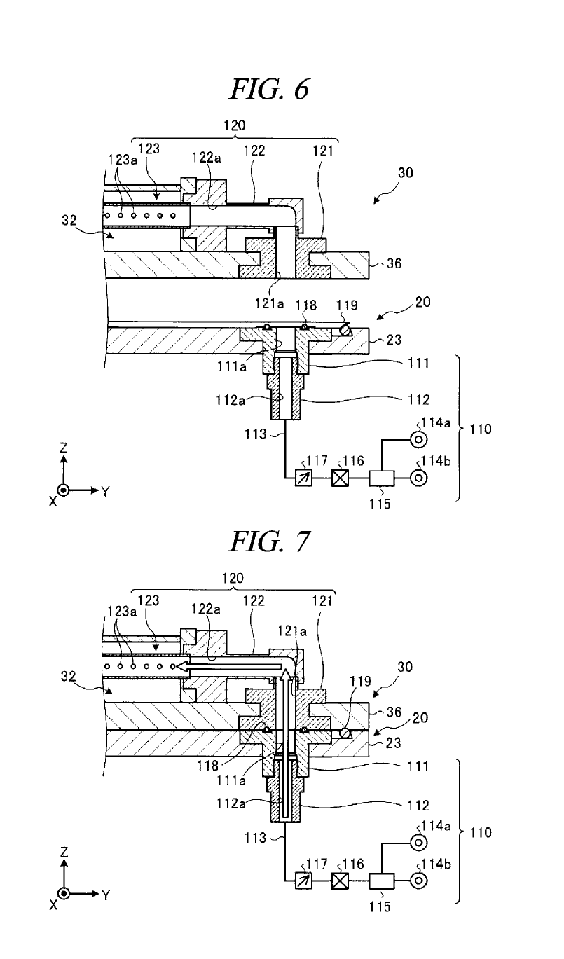

Now, the configuration of the supply path for the drying fluid will be explained with reference to FIG. 6 and FIG. 7. FIG. 6 is a schematic cross sectional view illustrating the configuration of the supply path for the drying fluid. FIG. 7 is a schematic cross sectional view illustrating a state in which an upstream supply path and a downstream supply path are connected. Further, FIG. 6 and FIG. 7 correspond to cross sectional views taken along a line A-A of FIG. 2.

As depicted in FIG. 6, the supply path for the drying fluid includes a stationary upstream path 110 and a downstream path 120 configured to be moved up and down along with the cover unit 30.

The upstream path 110 includes a connecting member 111, a joint member 112, a pipeline 113, an IPA supply source 114a, a hot N₂ gas supply source 114b, an IPA vapor generator 115, a valve 116 and a flow rate controller 117.

The connecting member 111 is provided in the first flange 23 of the processing chamber 20. The connecting member 111 has a flow passage 111a which penetrates through the first flange 23 vertically. The joint member 112 connects the connecting member 111 and the pipeline 113. The joint member 112 has a vertically extended flow passage 112a. The flow passage 112a communicates with the pipeline 113 at an upstream end thereof and communicates with the flow passage 111a at a downstream end thereof.

A seal member 118 is provided at a top surface of the connecting member 111, that is, a surface of the connecting member 111 facing the connecting member 121. The seal member 118 is, by way of non-limiting example, an O-ring and provided around the downstream end of the flow passage 111a. Further, a seal member 119 is provided at a top surface of the first flange 23, that is, a surface of the first flange 23 facing the second flange 36. The seal member 119 may be, by way of non-limiting example, a lip seal and provided at an outer side of the first flange 23 than the connecting member 111 is.

The pipeline 113 is connected to the IPA vapor generator 115 via the valve 116 and the flow rate controller 117. The IPA vapor generator 115 is connected to the IPA supply source 114a and the hot N₂ supply source 114b. By mixing IPA supplied from the IPA supply source 114a and a hot N₂ gas (heated nitrogen gas) supplied from the hot N₂ gas supply source 114b, the IPA vapor generator 115 generates IPA vapor by vaporizing the IPA with heat of the hot N₂ gas. The IPA vapor generator 115 supplies the generated IPA vapor to the pipeline 113. Further, in case of supplying only the hot N₂ gas to the IPA vapor generator 115 without supplying the IPA thereto, the hot N₂ gas is supplied into the pipeline 113 from the IPA vapor generator 115. The valve 116 is provided at a portion of the pipeline 113 and opens or closes the pipeline 113. The flow rate controller 117 is provided at a portion of the pipeline 113 and adjusts a flow rate of the IPA vapor or the hot N₂ gas flowing in the pipeline 113.

The downstream path 120 includes the connecting member 121, the joint member 122 and the nozzles 123. The connecting member 121 is provided at the second flange 36. The connecting member 121 has a flow passage 121a which penetrates through the second flange 36 vertically. The joint member 122 connects the connecting member 121 and the nozzles 123. The joint member 122 has a flow passage 122a extended in the horizontal direction. The flow passage 122a communicates with the flow passage 121a at an upstream end thereof and communicates with the nozzles 123 at a downstream end thereof.

As stated above, the supply path for the drying fluid is divided into the upstream path 110 and the downstream path 120. When the cover unit 30 closes the first opening 21 by being lowered by the first elevating device 31 (see FIG. 1), the upstream path 110 and the downstream path 120 are connected with each other, so that the supply path for the drying fluid is completed. To elaborate, as shown in FIG. 7, as the connecting member 121 of the downstream path 120 is connected to the connecting member 111 of the upstream path 110, the flow passages 111a and 112a of the upstream path 110 and the flow passages 121a and 122a of the downstream path 120 respectively communicate with each other. As a result, the IPA vapor or the hot N₂ gas supplied from the IPA vapor generator 115 can be supplied into the diffusion space 32 from the multiple number of discharge openings 123a of the nozzles 123. Furthermore, as the cover member 30 is moved up, the connecting member 121 of the downstream path 120 is separated from the connecting member 111 of the downstream path 110, so that the connection between the upstream path 110 and the downstream path 120 is released.

In the state that the cover unit 30 is located at the closing position, the connecting member 121 of the downstream path 120 is in contact with the seal member 118 which is provided at the connecting member 111 of the upstream path 110. Accordingly, a leakage of the drying fluid between the flow passage 111a of the upstream path 110 and the flow passage 121a of the downstream path 120 can be suppressed. Furthermore, in the state that the cover unit 30 is placed at the closing position, the second flange 36 of the cover unit 30 is in contact with the seal member 119 provided at the first flange 23 of the processing chamber 20. Accordingly, a leakage of the drying fluid from the gap between the processing chamber 20 and the cover unit 30 can be suppressed.

As stated above, by dividing the supply path for the drying fluid into the upstream path 110 and the downstream path 120, a portion of the supply path for the drying fluid which is moved along with the cover unit 30 can be reduced. Thus, an influence of dust generation caused by the movement of the supply path for the drying fluid can be reduced.

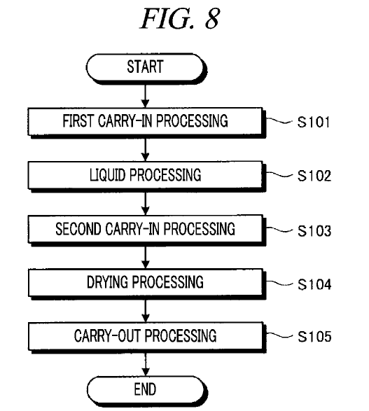

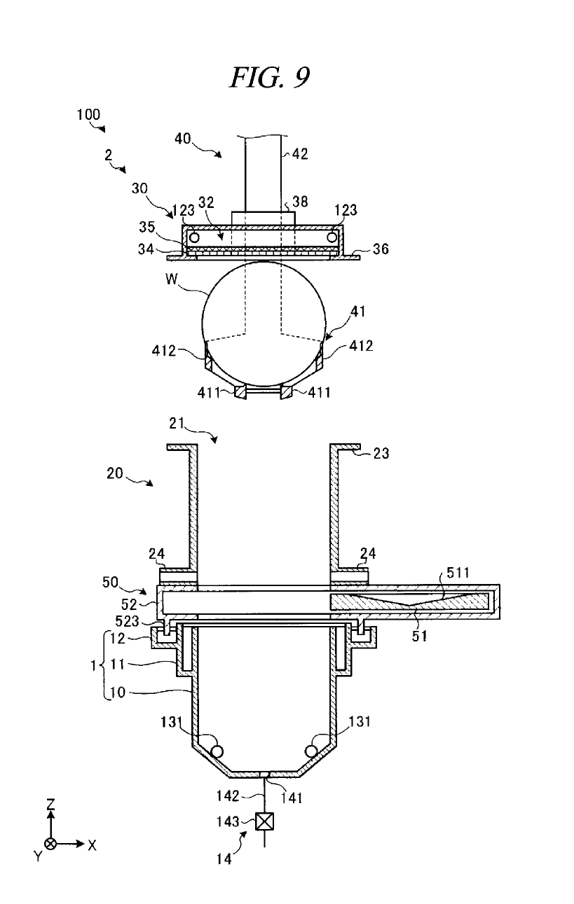

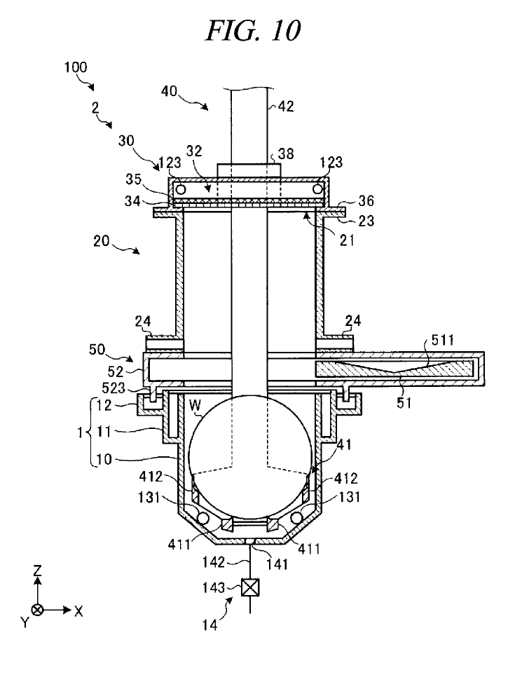

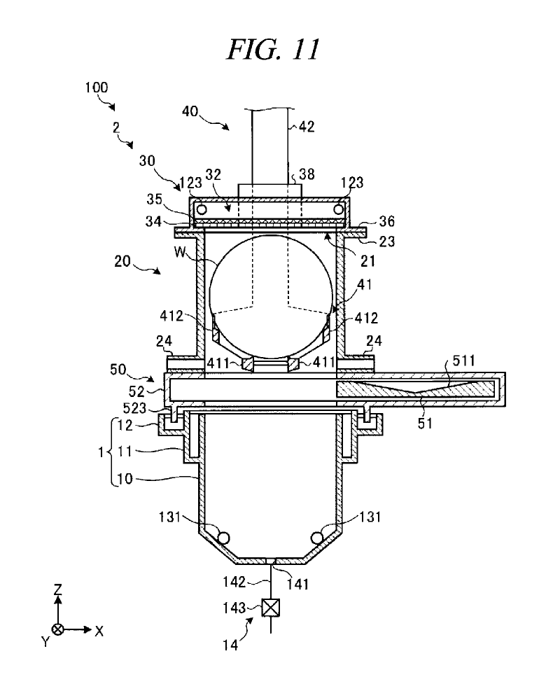

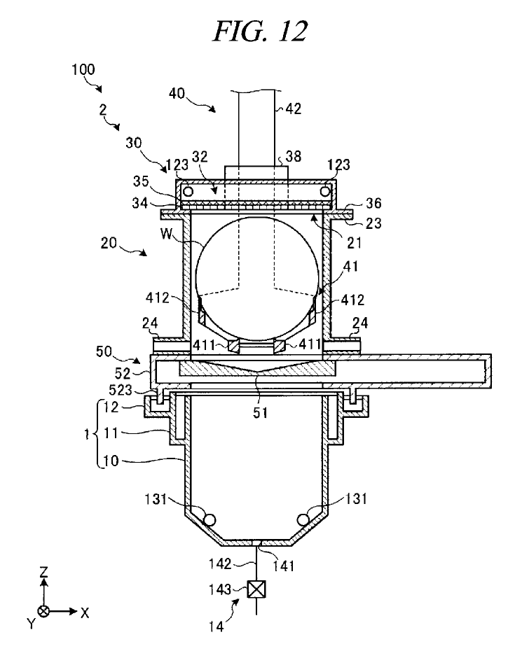

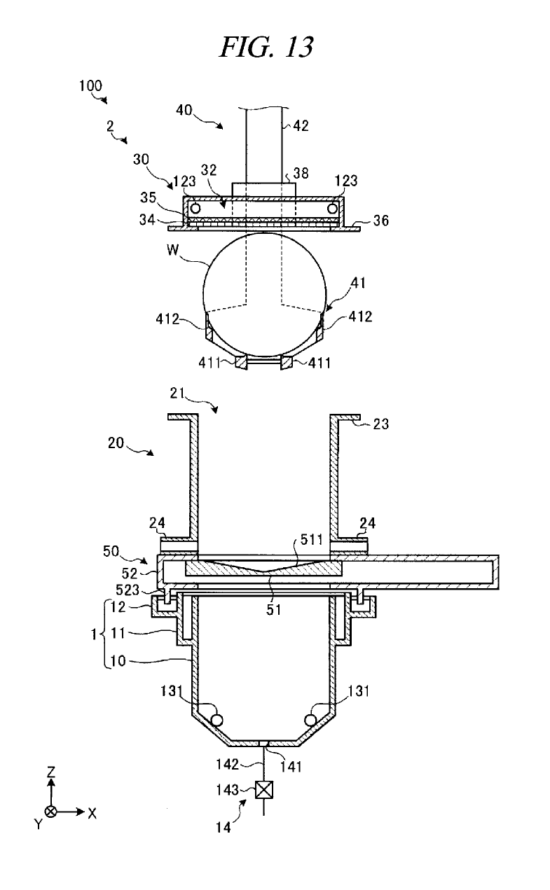

Now, a specific operation of the substrate processing apparatus 100 according to the exemplary embodiment will be explained with reference to FIG. 8 to FIG. 13. FIG. 8 is a flowchart showing an example sequence of a processing performed by the substrate processing apparatus 100. Further, FIG. 9 is a diagram illustrating an operation example of a first carry-in processing; FIG. 10, a diagram illustrating an operation example of a liquid processing; FIG. 11, a diagram illustrating an operation example of a second carry-in processing; FIG. 12, a diagram illustrating an operation example of a drying processing; and FIG. 13, a diagram illustrating an operation example of a carry-out processing.

As shown in FIG. 8, in the substrate processing apparatus 100, the first carry-in processing of carrying the wafers W into the storage tub 10 is performed (process S101). To elaborate, the control unit 81 controls a non-illustrated substrate transfer device to deliver the wafers W to the holding unit 41 of the transfer unit 40 (see FIG. 9). Then, the control unit 81 controls the first elevating device 31 and the second elevating device 43 to lower the cover unit 30 and the arm 42, so that the cover unit 30 is located at the closing position. Accordingly, the upstream path 110 and the downstream path 120 are connected with each other (see FIG. 7), and the hot N₂ gas is supplied into the processing chamber 20 from the nozzles 123 via the diffusion space 32, the pressure loss member 35 and the rectifying member 34. Thereafter, the control unit 81 controls the second elevating device 43 to further lower the arm 42, so that the wafers W held by the holding unit 41 are carried into the storage tub 10 (see FIG. 10).

Prior to this first carry-in processing, the substrate processing apparatus 100 may perform a stand-by processing. In the stand-by processing, by supplying the hot N₂ gas into the processing chamber 120 from the nozzles 123 in the state that the processing chamber 20 is sealed, that is, in the state that the cover unit 30 and the shielding door 51 are located at the closing positions, the inside of the processing chamber 20 is adjusted to have a predetermined temperature. Thereafter, by raising the cover unit 30 and the holding unit 41, the holding unit 41 is placed at a wafer receiving position shown in FIG. 9, and, then, the first carry-in processing is performed.

Though the processing liquid is constantly supplied into the storage tub 10 from the processing liquid discharge nozzles 131, to reduce the consumption amount thereof, a flow rate of the processing liquid in the standby-processing may be set to be a half of a flow rate set in the liquid processing.

Subsequently, in the substrate processing apparatus 100, the liquid processing of processing the wafers W with the processing liquid is performed (process S102). To elaborate, the control unit 81 allows the wafers W to be immersed in the storage tub 10 for a preset time period in a state that the flow rate of the processing liquid supplied into the storage tub 10 from the processing liquid discharge nozzles 131 is increased by controlling the flow rate controller 135. Here, it is assumed that a rinsing processing is performed by using a rinse liquid.

Then, in the substrate processing apparatus 100, the second carry-in processing of carrying the wafers W into the processing chamber 20 of the substrate drying apparatus 2 is performed (process S103). To elaborate, the control unit 81 controls the second elevating device 43 of the transfer unit 40 to raise the arm 42, so that the wafers W held by the holding unit 41 are raised from the storage tub 10 to be placed within the processing chamber 20 of the substrate processing apparatus 2 (see FIG. 11). Afterwards, the control unit 81 controls the moving device 53 of the shielding mechanism 50 to move the shielding door 51 at the closing position (see FIG. 12). Accordingly, the processing chamber 20 is hermetically sealed by the cover unit 30 and the shielding door 51.

Subsequently, in the substrate processing apparatus 100, the drying processing of removing the processing liquid from the wafers W is performed (process S104). To elaborate, the control unit 81 generates the IPA vapor by supplying the IPA and the hot N₂ gas into the IPA vapor generator 115 (see FIG. 6). The IPA vapor generated in the IPA vapor generator 115 is supplied into the diffusion space 32 via the upstream path 110 and the downstream path 120 and then is supplied into the processing chamber 20 from the diffusion space 32. The IPA vapor supplied in the diffusion space 32 is diffused within the diffusion space 32, and then, discharged out into the processing chamber 20 after the flow of the IPA vapor is rectified by the rectifying member 34. As a result, a downflow of the IPA vapor is formed within the processing chamber 20 (see FIG. 5). Accordingly, the IPA vapor is uniformly supplied to the wafers W placed within the processing chamber 20.

The IPA vapor comes into contact with a front surface and a rear surface of each wafer W, and then, is condensed on the front surface and the rear surface of each wafer W. The processing liquid remaining on the front surface and the rear surface of the wafer W is replaced by this condensed IPA. Then, by stopping the supply of the IPA from the IPA supply source 114a into the IPA vapor generator 115, the control unit 81 supplies the hot N₂ gas into the diffusion space 32 from the nozzles 123. Accordingly, a downflow of the hot N₂ gas is formed within the processing chamber 20, and the hot N₂ gas is uniformly supplied to the wafers W placed within the processing chamber 20. As the hot N₂ gas is supplied to the wafers W, volatilization of the IPA remaining on the front surface and the rear surface of each wafer W is accelerated, so that the wafers W are dried.

Subsequently, in the substrate processing apparatus 100, the carry-out processing of carrying out the wafers W from the processing chamber 20 is performed (process S105). To elaborate, the control unit 81 controls the first elevating device 31 and the second elevating device 43 to raise the cover unit 30 and the holding unit 41 (see FIG. 13). Then, by controlling the non-illustrated substrate transfer device, the control unit 81 delivers the wafers W to the non-illustrated substrate transfer device from the holding unit 41, and the series of substrate processings by the substrate processing apparatus 100 are completed.

Further, in the series of substrate processings, the gap between the insertion through hole 37 of the cover unit 30 and the arm 42 of the transfer unit 40 is constantly kept hermetically sealed by the sealing member 38. Without being limited to this configuration, however, if the sealing member 38 physically seals the gap between the insertion through hole 37 and the arm 42 by using the inflate seal or the like, the control unit 81 may release the sealed state by the sealing member 38 when moving only the holding unit 41 between the cover unit 30 and the holding unit 41 in the second carry-in processing.

As stated above, the substrate drying apparatus 2 according to the exemplary embodiment is a substrate drying apparatus configured to dry the wafer W (an example of a substrate), and is equipped with the processing chamber 20 and the cover unit 30. The processing chamber 20 has the first opening 21 (an example of an opening) through which the wafer W is carried out. The cover unit 30 is capable of opening or closing the first opening 21. Further, the cover unit has the diffusion space 32 and the rectifying member 34. The diffusion space 32 diffuses the drying fluid. Further, the rectifying member 34 rectifies the flow of the drying fluid diffused in the diffusion space 32 and allows the rectified drying fluid to be flown into the processing chamber 20. Thus, in the substrate drying apparatus 2 according to the present exemplary embodiment, the drying fluid can be uniformly supplied to the wafers W.

Further, the substrate drying apparatus 2 is equipped with the upstream path 110 configured to supply the drying fluid and the downstream path 120 configured to introduce the drying fluid supplied from the upstream path 110 into the diffusion space 32. The downstream path 120 is provided in the cover unit 30. The downstream path 120 is connected to the upstream path 110 when the cover unit 30 is located at the closing position where the cover unit 30 closes the first opening 21, and is separated from the upstream path 110 when the cover unit 30 is located at the opening position where the cover unit 30 opens the first opening 21. As stated, by adopting the configuration in which the supply path for the drying fluid is divided into the upstream path 110 and the downstream path 120, a portion of the supply path, which is moved along with the cover unit 30, is reduced. Therefore, an adverse influence from the dust generation or the like can be reduced.

Further, the processing chamber 20 has the first flange 23 around the first opening 21, and the cover unit 30 has the second flange 36 facing the first flange 23. The upstream path 110 includes, in the first flange 23, the connecting member 111 configured to be connected to the downstream path 120, and the downstream path 120 includes, in the second flange 36, the connecting member 121 configured to be connected to the upstream path 110. With this configuration, the closing of the first opening 21 and the connection between the upstream path 110 and the downstream path 120 can both be carried out only by a single operation of lowering the cover unit 30.

Further, the connecting member 111 and the joint member 112 of the upstream path 110 may not necessarily provided in the processing chamber 20, and may be fixed to a certain position other than the processing chamber 20.

Furthermore, the first opening 21 is provided at the upper portion of the processing chamber 20, and the processing chamber 20 has the exhaust ports 24 for the drying fluid which are provided under the wafers W placed within the processing chamber 20. Accordingly, the vertical flow of the drying fluid flowing downwards from the first opening 21 can be easily maintained up to under the wafers W, so that the drying fluid can be more uniformly supplied to the wafers W.

Further, the cover unit 30 is equipped with the pressure loss member 35 configured to cause the pressure loss on the drying fluid which is introduced into the rectifying member 34 from the diffusion space 32. Accordingly, since the drying fluid can be diffused within the diffusion space 32 with higher density, the generation of the non-uniformity in the flow rate of the drying fluid discharged from the rectifying member 34 can be further suppressed, so that the appropriate downflow without suffering the swirling-up can be formed within the processing chamber 20.

Moreover, the substrate drying apparatus 2 is equipped with the first elevating device 31 configured to move the cover unit 30 up and down, the holding unit 41 configured to hold the wafers W, the arm 42 configured to support the holding unit 41, and the second elevating device 43 configured to move the arm 42 up and down. Further, the cover unit 30 is provided with the insertion through hole 37 through which the arm 42 is inserted. With this configuration, the cover unit 30 and the holding unit 41 can be moved up and down independently.

Furthermore, the cover unit 30 is equipped with the sealing member 38 configured to seal the gap between the insertion through hole 37 and the arm 42. Accordingly, the leakage of the drying fluid from the gap between the insertion through hole 37 and the arm 42 can be suppressed.

The sealing member 38 seals the gap between the insertion through hole 37 and the arm 42 by setting the pressure within the gap between the insertion through hole 37 and the arm 42 to be higher than the pressure within the processing chamber 20 while supplying the gas into the gap between the insertion through hole 37 and the arm 42. Accordingly, as compared to the case of physically sealing the gap between the insertion through hole 37 and the arm 42 by using, for example, the inflate seal or the like, the influence from the dust generation or the like can be reduced. In addition, even when moving the cover unit 30 and the holding unit 41 independently as in the first carry-in processing or the second carry-in processing, for example, the state in which the gap between the insertion through hole 37 and the arm 42 is hermetically sealed can be maintained.

### Modification Example

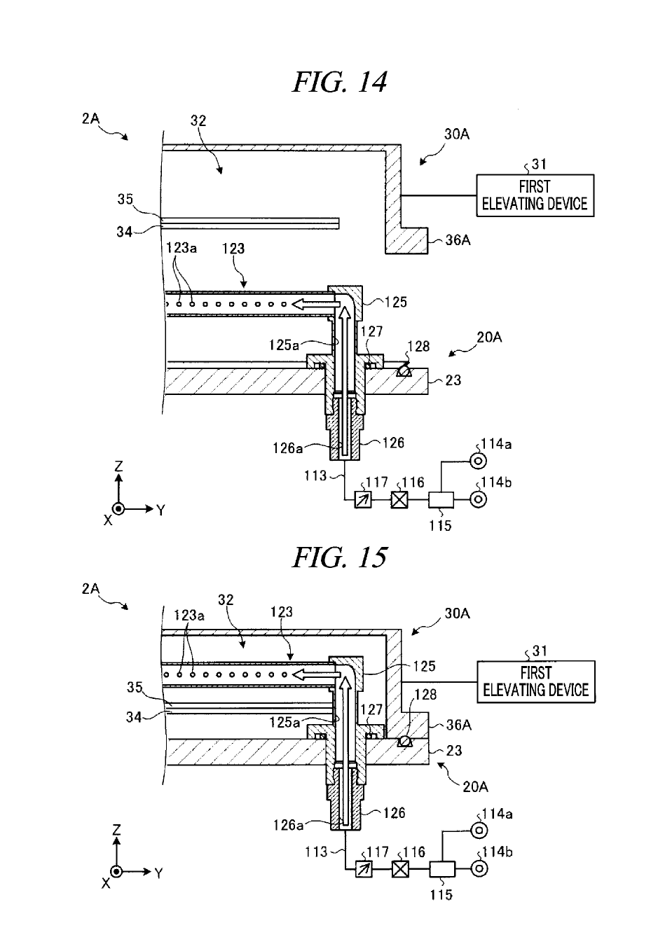

In the above-described exemplary embodiment, although the supply path for the drying fluid is divided into the upstream path 110 and the downstream path 120, and the nozzles 123 are provided at the cover unit 30, the nozzles 123 may be provided in the processing chamber 20. FIG. 14 and FIG. 15 are schematic cross sectional views of a substrate drying apparatus according to a modification example.

By way of example, as shown in FIG. 14, a substrate drying apparatus 2A is equipped with a processing chamber 20A and the cover unit 30A. The processing chamber 20A includes the nozzle 123, a nozzle fixing member 125 and a joint member 126. The nozzle fixing member 125 has a flow passage 125a which penetrates through the first flange 23 vertically. The flow passage 125a communicates with the nozzle 123 at a downstream end thereof. The joint member 126 connects the nozzle fixing member 125 and the pipeline 113. The joint member 126 has a vertically extended flow passage 126a. The flow passage 126a communicates with the pipeline 113 at an upstream end thereof and communicates with the flow passage 125a at a downstream end thereof. The pipeline 113 is connected to the IPA vapor generator 115 via the valve 116 and the flow rate controller 117. The IPA vapor generator 115 is connected to the IPA supply source 114a and the hot N₂ gas supply source 114b.

A seal member 127 is provided between the nozzle fixing member 125 and the first flange 23. The seal member 127 may be, by way of non-limiting example, an O-ring and suppresses a leakage of the drying fluid from the gap between the nozzle fixing member 125 and the first flange 23. Further, a seal member 128 is provided at the top surface of the first flange 23, that is, a surface of the first flange 23 facing a second flange 36A of the cover unit 30A. The seal member 128 may be, by way of non-limiting example, a lip seal and is provided at an outer side of the first flange 23 than the nozzle fixing member 125 is.

The cover unit 30A is equipped with the diffusion space 32, the rectifying member 34 and the pressure loss member 35. The cover unit 30A is not provided with the downstream path 120, that is, the connecting member 121, the joint member 122 and the nozzles 123.

In the substrate drying apparatus 2A according to the modification example, as the cover unit 30A is lowered by the first elevating device 31 to be located at the closing position, the nozzles 123 are placed within the diffusion space 32, as shown in FIG. 15. Accordingly, the IPA vapor or the hot N₂ gas supplied from the IPA vapor generator 115 is supplied into the diffusion space 32 from the nozzles 123. As stated above, the nozzles 123 may be provided in the processing chamber 20A.

In the above-described exemplary embodiment and the modification example, the substrate drying apparatus 2 (2A) is equipped with the nozzle 123. However, the substrate drying apparatus 2 (2A) need not necessarily be equipped with the nozzle 123. By way of example, the substrate drying apparatus 2 may supply the drying fluid into the diffusion space 32 directly from the flow passage 122a of the joint member 122. Further, the substrate drying apparatus 2A may supply the drying fluid into the diffusion space 32 from the flow passage 125a of the nozzle fixing member 125.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate drying apparatus configured to dry a substrate, comprising:
a processing chamber provided with an opening through which the substrate is carried in and out; and
a cover unit configured to open or close the opening,
wherein the cover unit comprises:
a diffusion space configured to diffuse a drying fluid therein; and
a rectifying member configured to rectify a flow of the drying fluid diffused in the diffusion space and allow the rectified drying fluid to be flown out into the processing chamber from the diffusion space.

2. The substrate drying apparatus of claim 1, further comprising:
an upstream path configured to supply the drying fluid; and
a downstream path configured to introduce the drying fluid supplied from the upstream path into the diffusion space,
wherein the downstream path is provided at the cover unit, and is connected to the upstream path when the cover unit is located at a closing position where the cover unit closes the opening and separated from the upstream path when the cover unit is placed at an opening position where the cover unit opens the opening.

3. The substrate drying apparatus of claim 2,
wherein the processing chamber comprises a first flange around the opening,
the cover unit comprises a second flange facing the first flange,
the upstream path includes, in the first flange, a connecting member configured to be connected to the downstream path, and
the downstream path includes, in the second flange, a connecting member configured to be connected to the upstream path.

4. The substrate drying apparatus of claim 3,
wherein the opening is provided at an upper portion of the processing chamber, and
the processing chamber is provided with an exhaust port for the drying fluid located under the substrate which is placed in the processing chamber.

5. The substrate drying apparatus of claim 3,
wherein the cover unit comprises a pressure loss member configured to cause a pressure loss on the drying fluid introduced into the rectifying member from the diffusion space.

6. The substrate drying apparatus of claim 3, further comprising:
a first elevating device configured to move the cover unit up and down;
a holding unit configured to hold the substrate;
an arm configured to support the holding unit; and
a second elevating device configured to move the arm up and down,
wherein the cover unit is provided with an insertion through hole through which the arm is inserted.

7. The substrate drying apparatus of claim 2,
wherein the opening is provided at an upper portion of the processing chamber, and
the processing chamber is provided with an exhaust port for the drying fluid located under the substrate which is placed in the processing chamber.

8. The substrate drying apparatus of claim 7, further comprising:
a first elevating device configured to move the cover unit up and down;
a holding unit configured to hold the substrate;
an arm configured to support the holding unit; and
a second elevating device configured to move the arm up and down,
wherein the cover unit is provided with an insertion through hole through which the arm is inserted.

9. The substrate drying apparatus of claim 2,
wherein the cover unit comprises a pressure loss member configured to cause a pressure loss on the drying fluid introduced into the rectifying member from the diffusion space.

10. The substrate drying apparatus of claim 9,
wherein the pressure loss member is a porous member or a member processed by punching.

11. The substrate drying apparatus of claim 9, further comprising:
a first elevating device configured to move the cover unit up and down;
a holding unit configured to hold the substrate;
an arm configured to support the holding unit; and
a second elevating device configured to move the arm up and down,
wherein the cover unit is provided with an insertion through hole through which the arm is inserted.

12. The substrate drying apparatus of claim 1,
wherein the opening is provided at an upper portion of the processing chamber, and
the processing chamber is provided with an exhaust port for the drying fluid located under the substrate which is placed in the processing chamber.

13. The substrate drying apparatus of claim 12, further comprising:
a first elevating device configured to move the cover unit up and down;
a holding unit configured to hold the substrate;
an arm configured to support the holding unit; and
a second elevating device configured to move the arm up and down,
wherein the cover unit is provided with an insertion through hole through which the arm is inserted.

14. The substrate drying apparatus of claim 13,
wherein the cover unit includes a sealing member configured to seal a gap between the insertion through hole and the arm.

15. The substrate drying apparatus of claim 13,
wherein the substrate drying apparatus is placed above a liquid processing tub configured to store a processing liquid therein,
the substrate drying apparatus further comprises a control unit configured to control the first elevating device and the second elevating device,
the control unit is configured to perform a first carry-in processing of controlling the first elevating device and the second elevating device to lower the cover unit and the arm to locate the cover unit at the closing position where the cover unit closes the opening and allow the substrate held by the holding unit to be placed within the liquid processing tub; a second carry-in processing of placing, after a liquid processing is performed on the substrate by the processing liquid stored in the liquid processing tub, the substrate held by the holding unit within the processing chamber by raising only the arm; and a carry-out processing of raising, after a drying processing using the drying fluid is performed on the substrate in the processing chamber, the cover unit and the arm to locate the cover unit at the opening position where the cover unit opens the opening and carry out the substrate held by the holding unit from the processing chamber.

16. The substrate drying apparatus of claim 1,
wherein the cover unit comprises a pressure loss member configured to cause a pressure loss on the drying fluid introduced into the rectifying member from the diffusion space.

17. The substrate drying apparatus of claim 16,
wherein the pressure loss member is a porous member or a member processed by punching.

18. The substrate drying apparatus of claim 16, further comprising:
a first elevating device configured to move the cover unit up and down;
a holding unit configured to hold the substrate;
an arm configured to support the holding unit; and
a second elevating device configured to move the arm up and down,
wherein the cover unit is provided with an insertion through hole through which the arm is inserted.

19. The substrate drying apparatus of claim 18,
wherein the cover unit includes a sealing member configured to seal a gap between the insertion through hole and the arm.

20. The substrate drying apparatus of claim 19,
wherein the sealing member seals the gap by setting a pressure within the gap between the insertion through hole and the arm to be higher than a pressure within the processing chamber while supplying a gas into the gap.
